(19) United States
(12) Patent Application Publication
(10) Pub. No.: US 2026/0006958 A1
(43) Pub. Date: Jan. 1, 2026

(54) MICRO CONTROL ELEMENT AND DISPLAY DEVICE

(71) Applicant: AUO Corporation, Hsinchu City (TW)

(72) Inventors: Yu Chun Yen, Hsinchu City (TW); Yu-Sheng Huang, Hsinchu City (TW)

(73) Assignee: AUO Corporation, Hsinchu City (TW)

(21) Appl. No.: 18/954,436

(22) Filed: Nov. 20, 2024

(30) Foreign Application Priority Data
Jun. 26, 2024 (TW) 113123807

(51) Int. Cl. H01L 33/62; H01L 25/075; H01L 25/16

(52) U.S. Cl. CPC H10H 20/857; H01L 25/0753; H01L 25/167

(57) ABSTRACT

A micro control element suitable for controlling multiple micro light emitting diodes is provided. The micro control element includes a substrate, multiple control units, and multiple output pins. The control units are disposed on the substrate, and the control units are grouped into multiple control-unit groups. The output pins are disposed on the substrate and suitable for being respectively connected to the micro light emitting diodes. At least a portion of the output pins are respectively disposed between the control-unit groups. A display device is also provided.

### CROSS-REFERENCE TO RELATED APPLICATION

This application claims the priority benefit of Taiwan application serial no. 113123807, filed on Jun. 26, 2024. The entirety of the above-mentioned patent application is hereby incorporated by reference herein and made a part of this specification.

### BACKGROUND

### Technical Field

The disclosure relates to a micro control element and a display device.

### Description of Related Art

Multiple micro light emitting diodes in a micro light emitting diode display may be controlled by a micro control element (a chip). Control units on a conventional chip are centrally disposed, so that multiple conducting wires connected to some output pins are required to be disposed in a manner of cross-layer traces to avoid short circuits with the adjacent conducting wires, which increases manufacturing costs of the micro light emitting diode display.

### SUMMARY

The disclosure provides a micro control element and a display device, and the display device using the micro control element may avoid use of cross-layer traces and reduce manufacturing costs.

According to an embodiment of the disclosure, a micro control element is provided, which is suitable for controlling multiple micro light emitting diodes, and includes a substrate, multiple control units, and multiple output pins. The control units are disposed on the substrate. The control units are grouped into multiple control-unit groups. The output pins are disposed on the substrate, and are suitable for being respectively connected to the micro light emitting diodes. At least a portion of the output pins are respectively disposed between the control-unit groups.

According to an embodiment of the disclosure, a display device is provided, which includes multiple micro light emitting diodes and the micro control element. The micro light emitting diodes are disposed in an array. The micro light emitting diodes are respectively connected to the output pins.

Based on the above, the control units on the micro control element provided in the embodiment of the disclosure are grouped, and the output pins are disposed between the control-unit groups. Accordingly, a spatial arrangement of the output pins is changed, so that conducting wires connected between the micro light emitting diodes and the output pins may be set as the traces on the same layer, without the cross-layer traces, and there is no issue of short circuits between the adjacent conducting wires, greatly reducing the manufacturing costs of the display device.

In order for the aforementioned features and advantages of the disclosure to be more comprehensible, embodiments accompanied with drawings are described in detail below.

### BRIEF DESCRIPTION OF THE DRAWINGS

FIG. 1 is a schematic view of a display device according to a comparative example.

FIGS. 2 to 9 are schematic views of a display device according to the first to eighth embodiments of the disclosure respectively.

### DETAILED DESCRIPTION OF DISCLOSED EMBODIMENTS

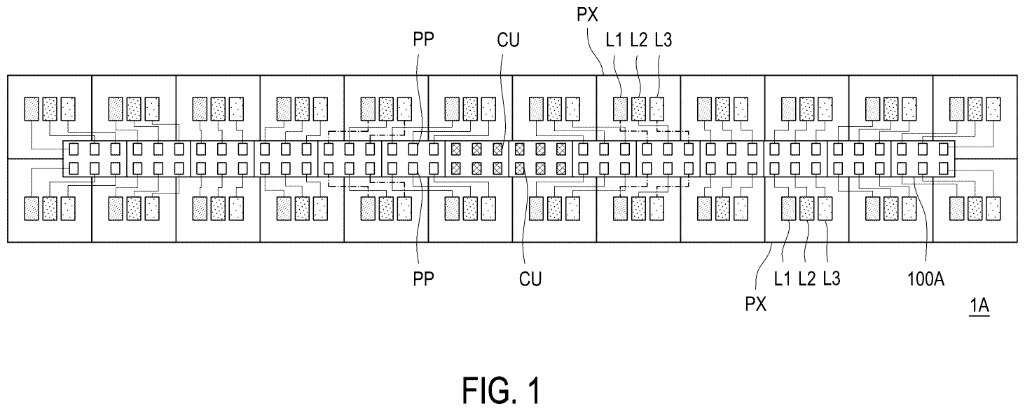

Referring to FIG. 1, FIG. 1 is a schematic view of a display device according to a comparative example. A display device 1A includes multiple pixel units PX arranged in an array and a micro control element 100A.

Each of the pixel units PX includes micro light emitting diodes L1, L2, and L3. The micro light emitting diodes L1, L2, and L3 may be, for example, a red micro light emitting diode, a green micro light emitting diode, and a blue micro light emitting diode respectively.

The micro control element 100A includes multiple control units CU and multiple output pins PP. The control units CU may include, for example, a power control unit and a signal control unit. The output pins PP are respectively connected to the micro light emitting diodes L1, L2, and L3 of the pixel units PX, as shown in FIG. 1.

As shown in FIG. 1, the control units CU in this comparative example are centrally disposed in a central area of the micro control element 100A, and the output pins PP are disposed in two side areas of the micro control element 100A, so that multiple conducting wires (multiple dotted lines shown in FIG. 1) connected to some of the output pins PP are required to be disposed in a manner of cross-layer traces to avoid short circuits with the adjacent conducting wires. That is to say, in the display device 1A in this comparative example, the conducting wires connected between the micro light emitting diodes L1, L2, and L3 and the output pins PP are not traces on the same layer, resulting in the display device 1A requiring higher manufacturing costs.

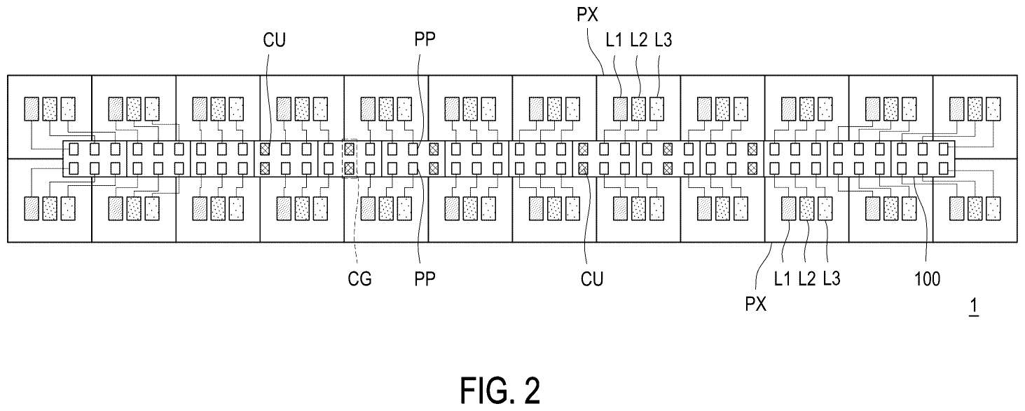

Next, referring to FIG. 2, FIG. 2 is a schematic view of a display device according to the first embodiment of the disclosure. A display device 1 includes the pixel units PX arranged in an array and a micro control element 100.

Each of the pixel units PX includes the micro light emitting diodes L1, L2, and L3. The micro light emitting diodes L1, L2, and L3 may be, for example, the red micro light emitting diode, the green micro light emitting diode, and the blue light emitting diode respectively.

The micro control element 100 includes a substrate, the control units CU, and the output pins PP. The control units CU and the output pins PP are disposed on the substrate, and are respectively located in upper and lower rows as shown in FIG. 2. The control units CU may include, for example, the power control unit and the signal control unit. The output pins PP are respectively connected to the micro light emitting diodes L1, L2, and L3 of the pixel units PX, as shown in FIG. 2.

The control units CU in this first embodiment are grouped in units of two control units CU to form multiple control-unit groups CG. That is to say, each of the control-unit groups CG includes two control units CU. In addition, the output pins PP are disposed between the control-unit groups CG, as shown in FIG. 2. Accordingly, a spatial arrangement of the output pins PP in this embodiment is different from a spatial arrangement of the output pins PP in the aforementioned comparative example, so that the conducting wires respectively connected between the micro light emitting diodes L1, L2, and L3 and the output pins PP may be set as traces on the same layer, without cross-layer traces, and there is no issue of short circuits between the adjacent conducting wires, greatly reducing manufacturing costs of the display device 1.

In this first embodiment, as shown in FIG. 2, the number of output pins PP disposed between the control-unit groups CG is a multiple of 3. The control units CU are grouped into 6 control-unit groups CG. The output pins PP on the substrate are grouped to be located in 7 areas on the substrate due to the 6 control-unit groups CG, forming 7 output pin groups.

In order to fully describe various implementations of the disclosure, other embodiments of the disclosure will be described below. It is noted that some of the reference numerals and descriptions of the above embodiment will apply to the following embodiments. The same reference numerals will represent the same or similar components and the descriptions of the same technical contents will be omitted. Reference may be made to the above embodiment for the omitted descriptions, which will not be repeated in the following embodiments.

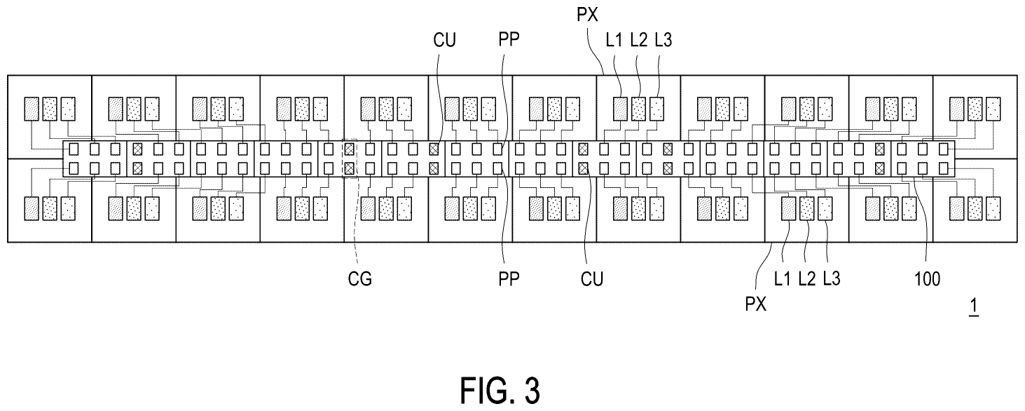

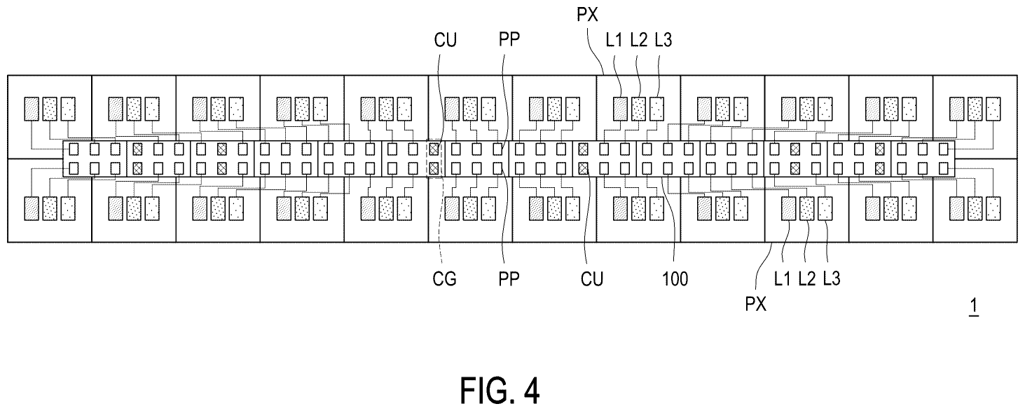

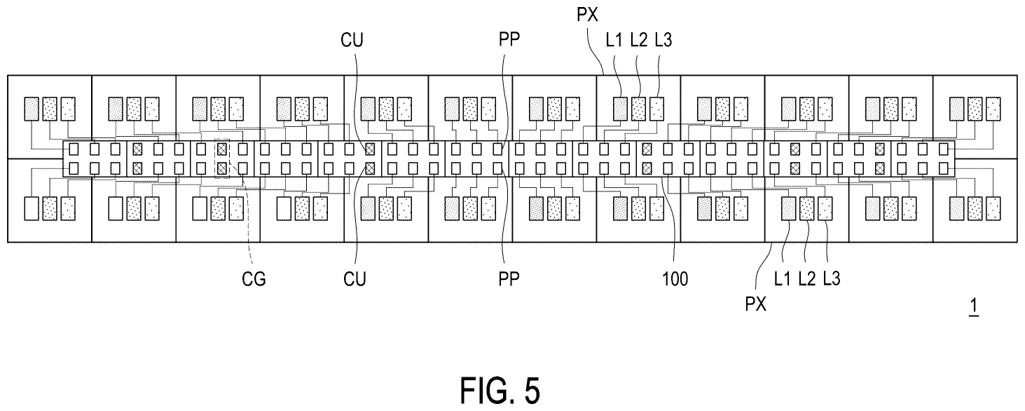

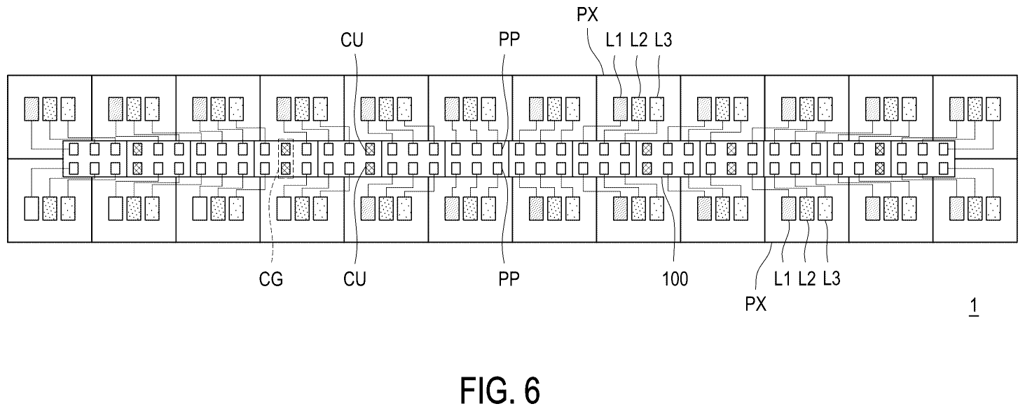

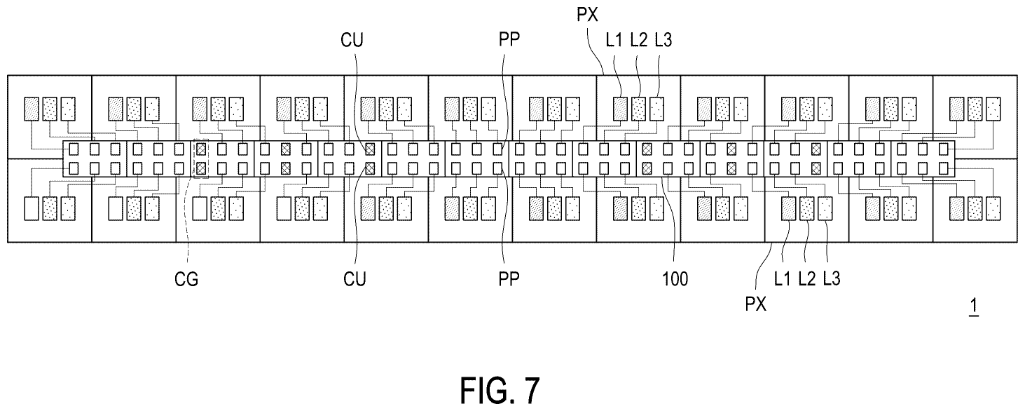

Next, referring to FIGS. 3 to 7, FIGS. 3 to 7 are schematic views of a display device according to the second to sixth embodiments of the disclosure. These embodiments are the same as the first embodiment in that the control units CU on the micro control element 100 are grouped in units of two control units CU to form the 6 control-unit groups CG. The output pins PP on the micro control element 100 are grouped to be located in the 7 areas on the substrate due to the 6 control-unit groups CG, forming the 7 output pin groups.

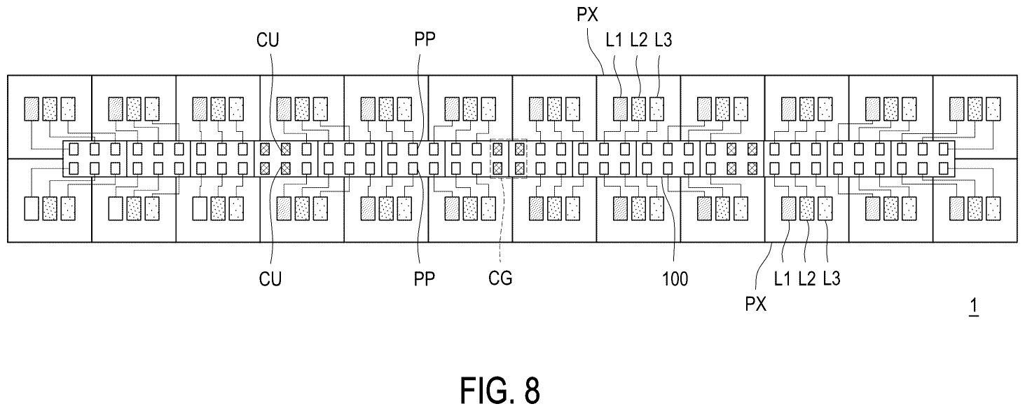

Next, referring to FIG. 8, FIG. 8 is a schematic view of a display device according to the seventh embodiment of the disclosure. A difference between this embodiment and the first embodiment is that the control units CU on the micro control element 100 are grouped in units of 4 control units CU to form 3 control-unit groups CG. The output pins PP on the micro control element 100 are grouped to be located in 4 areas on the substrate due to the 3 control-unit groups CG, forming 4 output pin groups.

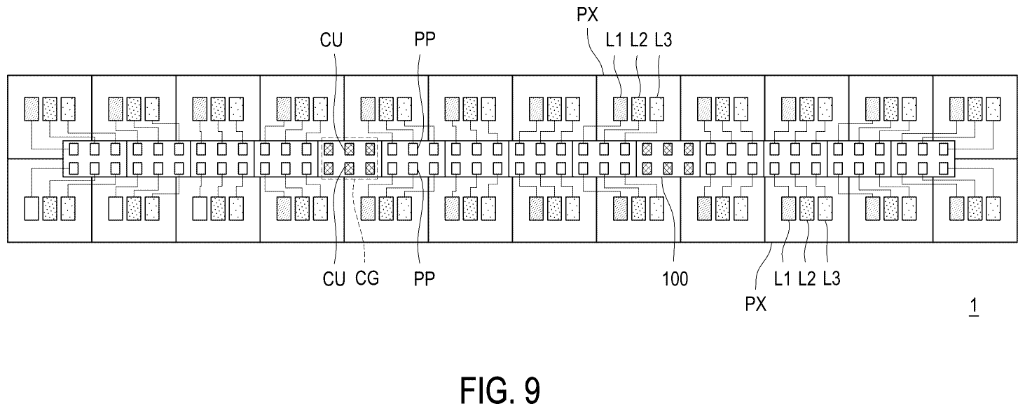

Next, referring to FIG. 9, FIG. 9 is a schematic view of a display device according to the eighth embodiment of the disclosure. A difference between this embodiment and the first embodiment is that the control units CU on the micro control element 100 are grouped in units of 6 control units CU to form 2 control-unit groups CG. The output pins PP on the micro control element 100 are grouped to be located in 3 areas on the substrate due to the 2 control-unit groups CG, forming 3 output pin groups.

Based on the above, according to the first to eighth embodiments of the disclosure, by grouping the control units on the micro control element and disposing the output pins between the control-unit groups, the spatial arrangement of the output pins may be changed, so that the conducting wires connected between the micro light emitting diodes and the output pins may be set as the traces on the same layer, without the cross-layer traces, and there is no issue of short circuits between the adjacent conducting wires, greatly reducing the manufacturing costs of the display device.

What is claimed is:

1. A micro control element, suitable for controlling a plurality of micro light emitting diodes, and comprising:
a substrate;
a plurality of control units disposed on the substrate, wherein the control units are grouped into a plurality of control-unit groups; and
a plurality of output pins disposed on the substrate and suitable for being respectively connected to the micro light emitting diodes,
wherein at least a portion of the output pins are respectively disposed between the control-unit groups.

2. The micro control element according to claim 1, wherein a number of the output pins disposed between the control-unit groups is a multiple of 3.

3. The micro control element according to claim 1, wherein the control units are grouped into the N control-unit groups, and the output pins are grouped into N+1 output pin groups.

4. The micro control element according to claim 3, wherein N=6.

5. The micro control element according to claim 3, wherein N=3.

6. The micro control element according to claim 3, wherein N=2.

7. The micro control element according to claim 1, wherein the substrate has a first side and a second side opposite to each other, and the control units are formed by the control units in a first row disposed on the first side and the control units in a second row disposed on the second side.

8. The micro control element according to claim 7, wherein the output pins are formed by the output pins in the first row disposed on the first side and the output pins in the second row disposed on the second side.

9. The micro control element according to claim 1, wherein the control units comprise a power control unit and a signal control unit.

10. A display device, comprising:
a plurality of micro light emitting diodes disposed in an array; and
the micro control element according to claim 1,
wherein the micro light emitting diodes are respectively connected to the output pins.

11. The display device according to claim 10, wherein a plurality of conducting wires respectively connected between the micro light emitting diodes and the output pins are traces on a same layer.
